(19) United States
(12) Patent Application Publication
(10) Pub. No.: US 2026/0309790 A1
(43) Pub. Date: Oct. 8, 2026

(54) SYSTEM AND METHOD FOR BATTERY STATE OF CHARGE DETERMINATION

(71) Applicant: GM Global Technology Operations LLC, Detroit, MI (US)

(72) Inventors: Justin Anthony Bunnell, Cary, NC (US); Balin Kumar Shrivastava, Waterford, MI (US); Alper Celikay, Commerce Township, MI (US); Heiko Escher, White Lake, MI (US)

(21) Appl. No.: 19/173,347

(22) Filed: Apr. 8, 2025

(51) Int. Cl. G01R 31/382; B60L 58/12; H01M 10/42; H01M 10/48

(52) U.S. Cl. CPC G01R 31/382; B60L 58/12; H01M 10/425; H01M 10/482; H01M 2010/4271; H01M 2220/20

(57) ABSTRACT

A method for determining a state of charge of each of a plurality of battery sections of a rechargeable energy storage system (RESS) may include determining a first state of charge of a first battery section of the plurality of battery sections. The method further may include discharging a first amount of charge from the first battery section in response to determining the first state of charge of the first battery section. The method further may include determining a second state of charge of the first battery section in response to discharging the first amount of charge from the first battery section. The method further may include determining the state of charge of each of the plurality of battery sections based at least in part on the first state of charge, the first amount of charge, and the second state of charge.

### INTRODUCTION

The present disclosure relates to systems and methods for battery state of charge determination.

To assess battery state of charge (SOC) in energy storage applications, battery management systems (BMS) may be utilized. A BMS is an electronic control unit typically including sensors and processing circuits configured to monitor key battery parameters such as capacity, SOC, and state of health (SOH) based on measurements of voltage, current, temperature, and/or the like. Battery SOC determination may involve various estimation techniques, including Coulomb counting, open-circuit voltage measurement, and predictive models. Additionally, BMS units may integrate real-time data logging and adaptive algorithms to improve accuracy over the battery's lifespan. Some implementations include thermal management features to prevent overheating and extend battery life. Multiple sensors and computational models may be used in tandem to enhance precision and reliability. Battery SOC determination is useful for optimizing performance in applications such as, for example, electric vehicles, renewable energy storage, and consumer electronics. Accurate SOC determination ensures efficient power utilization, increases battery lifespan, and enhances accuracy of other battery parameter determinations.

While systems and methods for battery parameter determination achieve their intended purpose, there is a need for new and improved systems and methods for determining SOC of batteries.

### SUMMARY

According to several aspects, a method for determining a state of charge of each of a plurality of battery sections of a rechargeable energy storage system (RESS) is provided. The method may include determining a first state of charge of a first battery section of the plurality of battery sections. The method further may include discharging a first amount of charge from the first battery section in response to determining the first state of charge of the first battery section. The method further may include determining a second state of charge of the first battery section in response to discharging the first amount of charge from the first battery section. The method further may include determining the state of charge of each of the plurality of battery sections based at least in part on the first state of charge, the first amount of charge, and the second state of charge.

In another aspect of the present disclosure, discharging the first amount of charge from the first battery section further may include determining a certainty of a state of charge estimate of each of the plurality of battery sections. Discharging the first amount of charge from the first battery section further may include comparing the certainty of the state of charge estimate of each of the plurality of battery sections to a predetermined state of charge certainty threshold. Discharging the first amount of charge from the first battery section further may include discharging the first amount of charge from the first battery section in response to determining that the certainty of the state of charge estimate of one or more of the plurality of battery sections is less than the predetermined state of charge certainty threshold.

In another aspect of the present disclosure, discharging the first amount of charge from the first battery section further may include determining a maximum permissible amount of charge to discharge from the first battery section. Discharging the first amount of charge from the first battery section further may include determining the first amount of charge based at least in part on the maximum permissible amount of charge. The first amount of charge is less than or equal to the maximum permissible amount of charge. Discharging the first amount of charge from the first battery section further may include discharging the first amount of charge from the first battery section in response to determining the first amount of charge.

In another aspect of the present disclosure, discharging the first amount of charge from the first battery section further may include discharging the first battery section until a certainty of a state of charge estimate of the first battery section is greater than or equal to a predetermined state of charge certainty threshold. The first amount of charge is equal to a total amount of charge removed from the first battery section while discharging the first battery section.

In another aspect of the present disclosure, discharging the first amount of charge from the first battery section further may include discharging the first amount of charge at least in part using an auxiliary power module (APM) configured to provide energy to low-voltage loads.

In another aspect of the present disclosure, discharging the first amount of charge from the first battery section further may include discharging the first amount of charge at least in part using the APM. The APM is a distributed APM including a plurality of distributed APM units. Each of the plurality of distributed APM units is configured to discharge one of the plurality of battery sections.

In another aspect of the present disclosure, discharging the first amount of charge from the first battery section further may include discharging the first amount of charge at least in part using the APM. The APM is a switched APM including a converter unit and a switching module. The switching module is configured to electrically connect the converter unit to any one of the plurality of battery sections.

In another aspect of the present disclosure, determining the state of charge of each of the plurality of battery sections further may include determining the state of charge of each of the plurality of battery sections based at least in part on the first state of charge, the first amount of charge, and the second state of charge using a formula:

$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}}$$

where SOCₙ is a state of charge of an nth battery section of the plurality of battery sections, SOC_{1,1} is the first state of charge of the first battery section, C₁ is a capacity of the first battery section, SOC_{1,2} is the second state of charge of the first battery section, ΔAh_{1,APM} is the first amount of charge, and Cₙ is a capacity of the nth battery section of the plurality of battery sections.

In another aspect of the present disclosure, determining the first state of charge further may include determining the first state of charge at a known reference state of the RESS. In the known reference state, each of the plurality of battery sections have a same state of charge.

In another aspect of the present disclosure, determining the first state of charge further may include determining the first state of charge. The first state of charge is between ninety percent and one hundred percent.

According to several aspects, a system for determining a state of charge of each of a plurality of battery sections of a rechargeable energy storage system (RESS) of a vehicle, the system may include the RESS including the plurality of battery sections electrically connected in series and an auxiliary power module (APM) in electrical communication with the RESS. The APM is configured to discharge one or more of the plurality of battery sections. The system further may include a controller in electrical communication with the plurality of battery sections and the APM. The controller is programmed to determine a first state of charge of a first battery section of the plurality of battery sections. The controller is further programmed to discharge a first amount of charge from the first battery section in response to determining the first state of charge of the first battery section. The controller is further programmed to determine a second state of charge of the first battery section in response to discharging the first amount of charge from the first battery section. The controller is further programmed to determine the state of charge of each of the plurality of battery sections based at least in part on the first state of charge, the first amount of charge, and the second state of charge.

In another aspect of the present disclosure, to discharge the first amount of charge from the first battery section, the controller is further programmed to determine a certainty of a state of charge estimate of each of the plurality of battery sections. To discharge the first amount of charge from the first battery section, the controller is further programmed to compare the certainty of the state of charge estimate of each of the plurality of battery sections to a predetermined state of charge certainty threshold. To discharge the first amount of charge from the first battery section, the controller is further programmed to discharge the first amount of charge from the first battery section in response to determining that the certainty of the state of charge estimate of one or more of the plurality of battery sections is less than the predetermined state of charge certainty threshold. The first battery section is discharged until a certainty of a state of charge estimate of the first battery section is greater than or equal to the predetermined state of charge certainty threshold. The first amount of charge is equal to a total amount of charge removed from the first battery section while discharging the first battery section.

In another aspect of the present disclosure, to discharge the first amount of charge from the first battery section, the controller is further programmed to determine a maximum permissible amount of charge to discharge from the first battery section based at least in part on an estimated range of the vehicle. To discharge the first amount of charge from the first battery section, the controller is further programmed to determine the first amount of charge based at least in part on the maximum permissible amount of charge. The first amount of charge is less than or equal to the maximum permissible amount of charge. To discharge the first amount of charge from the first battery section, the controller is further programmed to discharge the first amount of charge from the first battery section in response to determining the first amount of charge.

In another aspect of the present disclosure, the APM is configured to provide the first amount of charge to one or more low-voltage loads of the vehicle. The APM is a distributed APM including a plurality of distributed APM units. Each of the plurality of distributed APM units is configured to discharge one of the plurality of battery sections.

In another aspect of the present disclosure, the APM is configured to provide the first amount of charge to one or more low-voltage loads of the vehicle. The APM is a switched APM including a converter unit and a switching module. The switching module is configured to electrically connect the converter unit to any one of the plurality of battery sections.

In another aspect of the present disclosure, to determine the state of charge of each of the plurality of battery sections, the controller is further programmed to determine the state of charge of each of the plurality of battery sections based at least in part on the first state of charge, the first amount of charge, and the second state of charge using a formula:

$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}}$$

where SOCₙ is a state of charge of an nth battery section of the plurality of battery sections, SOC_{1,1} is the first state of charge of the first battery section, C₁ is a capacity of the first battery section, SOC_{1,2} is the second state of charge of the first battery section, ΔAh_{1,APM} is the first amount of charge, and Cₙ is a capacity of the nth battery section of the plurality of battery sections.

In another aspect of the present disclosure, the controller is further programmed to discharge a remainder of the plurality of battery sections using the APM in response to determining the state of charge of each of the plurality of battery sections. The remainder of the plurality of battery sections are discharged such that a state of charge deviation between each of the plurality of battery sections is less than a predetermined state of charge deviation threshold.

According to several aspects, a method for determining a state of charge of each of a plurality of battery sections of a rechargeable energy storage system (RESS) of a vehicle is provided. The method may include determining a first state of charge of a first battery section of the plurality of battery sections. The method further may include discharging a first amount of charge from the first battery section within a time period at least in part using an auxiliary power module (APM) configured to provide energy to low-voltage loads of the vehicle in response to determining the first state of charge of the first battery section. The first amount of charge is greater than an amount of charge discharged from a remainder of the plurality of battery sections within the time period. The method further may include determining a second state of charge of the first battery section in response to discharging the first amount of charge from the first battery section. The method further may include determining the state of charge of each of the plurality of battery sections based at least in part on the first state of charge, the first amount of charge, and the second state of charge using a formula:

$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}}$$

where SOCₙ is a state of charge of an nth battery section of the plurality of battery sections, SOC_{1,1} is the first state of charge of the first battery section, C₁ is a capacity of the first battery section, SOC_{1,2} is the second state of charge of the first battery section, ΔAh_{1,APM} is the first amount of charge, and Cₙ is a capacity of the nth battery section of the plurality of battery sections.

In another aspect of the present disclosure, discharging the first amount of charge from the first battery section further may include determining a certainty of a state of charge estimate of each of the plurality of battery sections. Discharging the first amount of charge from the first battery section further may include comparing the certainty of the state of charge estimate of each of the plurality of battery sections to a predetermined state of charge certainty threshold. Discharging the first amount of charge from the first battery section further may include discharging the first amount of charge from the first battery section in response to determining that the certainty of the state of charge estimate of one or more of the plurality of battery sections is less than the predetermined state of charge certainty threshold.

In another aspect of the present disclosure, discharging the first amount of charge from the first battery section further may include determining a maximum permissible amount of charge to discharge from the first battery section based at least in part on an estimated range of the vehicle. Discharging the first amount of charge from the first battery section further may include discharging the first battery section until a certainty of a state of charge estimate of the first battery section is greater than or equal to the predetermined state of charge certainty threshold or until the maximum permissible amount of charge has been discharged from the first battery section. The first amount of charge is equal to a total amount of charge removed from the first battery section while discharging the first battery section.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a system for determining state of charge of battery sections, according to an exemplary embodiment;

FIG. 2 is a schematic diagram of a distributed auxiliary power module, according to an exemplary embodiment;

FIG. 3 is a schematic diagram of a switched auxiliary power module, according to an exemplary embodiment;

FIG. 4 is a graph of an exemplary state of charge curve, according to an exemplary embodiment; and

FIG. 5 is a flowchart of a method for determining state of charge of battery sections, according to an exemplary embodiment.

### DETAILED DESCRIPTION

The following description is merely exemplary in nature and is not intended to limit the present disclosure, application, or uses.

The state of charge of a rechargeable battery is defined as an amount of charged stored in the battery relative to a capacity of the battery (i.e., a maximum amount of charge which the battery can store). In aspects of the present disclosure, it is advantageous to determine the state of charge of batteries for purposes of power limit determination, battery health management, diagnostics, and more. The fact that state of charge is not a directly measurable battery characteristic and the complex electro-chemical dynamics of batteries present challenges for state of charge determination and estimation. Accordingly, the present disclosure provides a new and improved system and method for battery state of charge determination which provides for accurate state of charge determination while minimizing impact on end users.

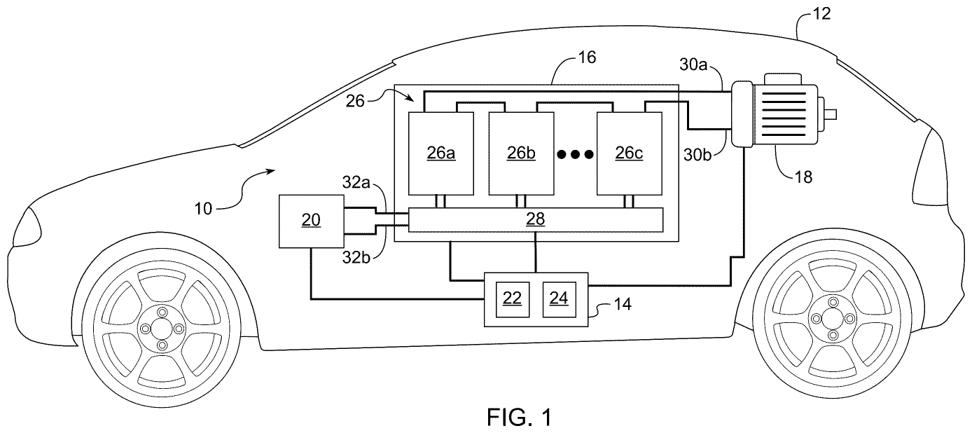

Referring to FIG. 1, a system for determining state of charge of battery sections is illustrated and generally indicated by reference number 10. The system 10 is shown with an exemplary vehicle 12. While a passenger vehicle is illustrated, it should be appreciated that the vehicle 12 may be any type of vehicle without departing from the scope of the present disclosure. The system 10 generally includes a controller 14, a rechargeable energy storage system (RESS) 16, a propulsion system 18, and a low-voltage system 20. It should be appreciated that the vehicle 12 may be any type of vehicle including an electro-chemical battery, including, for example, a battery-electric vehicle, a hybrid-electric vehicle, a plug-in-hybrid electric vehicle, an internal combustion engine vehicle and/or the like. It should also be appreciated that the vehicle 12 may include automobiles, trains, watercraft, aircraft, spacecraft, and/or any other type of self-propelled vehicle.

The controller 14 is used to implement a method 100 for determining state of charge of battery sections, as will be described below. The controller 14 includes at least one processor 22 and a non-transitory computer readable storage device or media 24. The processor 22 may be a custom made or commercially available processor, a central processing unit (CPU), a graphics processing unit (GPU), an auxiliary processor among several processors associated with the controller 14, a semiconductor-based microprocessor (in the form of a microchip or chip set), a macroprocessor, a combination thereof, or generally a device for executing instructions.

The computer readable storage device or media 24 may include volatile and nonvolatile storage in read-only memory (ROM), random-access memory (RAM), and keep-alive memory (KAM), for example. KAM is a persistent or non-volatile memory that may be used to store various operating variables while the processor 22 is powered down. The computer-readable storage device or media 24 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions, used by the controller 14 to control various systems of the vehicle 12.

The controller 14 may also include multiple controllers which are in electrical communication with each other. The controller 14 may be inter-connected with additional systems and/or controllers of the vehicle 12, allowing the controller 14 to access data such as, for example, speed, acceleration, braking, and steering angle of the vehicle 12.

The controller 14 is in electrical communication with the RESS 16, the propulsion system 18, and the low-voltage system 20. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 14 are within the scope of the present disclosure. It should further be understood that, in the scope of the present disclosure, electrical communication also includes power and/or energy transfer between electrical devices (e.g., using conducting wires and/or wireless power transmission techniques).

The RESS 16 stores and provides electrical energy in the form of direct current (DC) for propulsion of the vehicle 12 and operation of vehicle systems and features. In an exemplary embodiment, the RESS 16 includes a plurality of battery sections 26 and an auxiliary power module (APM) 28. In a non-limiting example, the RESS 16 includes a first battery section 26a, a second battery section 26b, and a third battery section 26c. It should be understood that the plurality of battery sections 26 may include any number of battery sections without departing from the scope of the present disclosure.

In an exemplary embodiment, each of the plurality of battery sections 26 includes one or more battery cells (e.g., lithium-ion battery cells) electrically connected in series and/or parallel. In a non-limiting example, each of the plurality of battery sections 26 is a serviceable unit of the RESS 16 housed in a modular enclosure configured to protect the battery cells from mechanical vibration, water intrusion, and dust intrusion. The enclosure is also configured to provide temperature regulation (e.g., using a liquid cooling system, a resistive heating system, and/or the like).

In an exemplary embodiment, the plurality of battery sections 26 are electrically connected together in series to provide high-voltage (e.g., 400 v or more) power to the propulsion system 18 via high-voltage terminals 30a, 30b. It should be understood that one or more of the plurality of battery sections 26 may also be electrically connected together in parallel to provide additional current-carrying capacity. Each of the plurality of battery sections 26 is connected to the APM 28 to provide low-voltage power to the low-voltage system 20, as will be discussed in greater detail below.

In an exemplary embodiment, the RESS 16 further includes a battery management system (BMS) configured to monitor battery characteristics such as a state of charge (SOC), state of health (SOH), temperature, and/or the like, and transmit the battery characteristics to the controller 14. In a non-limiting example, the BMS includes a BMS controller in electrical communication with a plurality of BMS sensors disposed within the enclosure of the RESS 16 (e.g., voltage sensors, current sensors, temperature sensors, and/or the like). In an exemplary embodiment, the BMS is in electrical communication with the controller 14. In a non-limiting example, the functions of the BMS controller are realized by program instructions executed by the controller 14. In another non-limiting example, the BMS controller is in electrical communication with the controller 14. In any case, the controller 14 is operable to control the BMS and/or the BMS controller and use the plurality of BMS sensors to monitor and/or determine battery characteristics of the RESS 16.

The APM 28 is used to provide energy to the low-voltage system 20 (e.g., auxiliary vehicle components, such as, for example, lighting, entertainment/infotainment systems, vehicle sensors, driver assistance systems, convenience features (e.g., heated seats), and/or the like). In an exemplary embodiment, the APM 28 includes one or more direct current (DC) to DC converters (e.g., buck converters, boost converters, buck-boost converters, flyback converters, and/or the like) and associated passive and/or active components (e.g., resistors, capacitors, inductors, transistors, etc.) configured to convert voltages provided by each of the plurality of battery sections 26 to low-voltage (e.g., 12 v, 24 v, 48 v, and/or the like) for powering the low-voltage system 20. In a non-limiting example, the APM 28 is connected in series with each of the one or more battery cells of each of the plurality of battery sections 26. In a non-limiting example, the APM 28 is connected in parallel across each of the one or more battery cells of each of the plurality of battery sections 26. The APM 28 is connected to the low-voltage system 20 via low-voltage terminals 32a, 32b. It should be understood that APM 28 may be realized with using any circuit(s) operable to transfer energy from the plurality of battery sections 26 to the low-voltage system 20, and more particularly, using any circuit(s) operable to selectively transfer energy from any one or more of the plurality of battery sections 26 to the low-voltage system 20, as will be discussed in greater detail below.

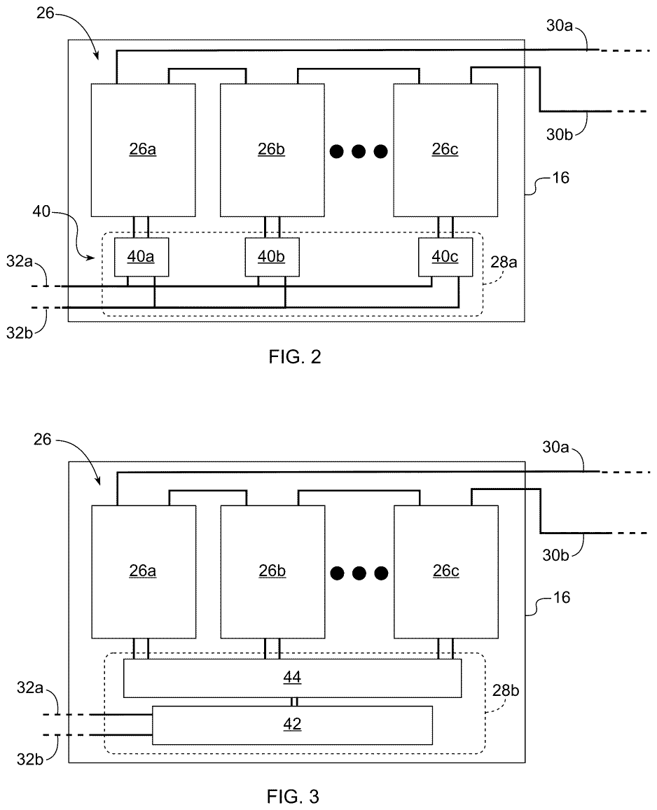

Referring to FIG. 2, a schematic diagram of the RESS 16 including a first exemplary embodiment of the APM 28 referred to as a distributed APM 28a is shown. In an exemplary embodiment, the distributed APM 28a includes a plurality of distributed APM units 40. Each of the plurality of distributed APM units 40 is configured to discharge one of the plurality of battery sections 26. In a non-limiting example, the plurality of distributed APM units 40 includes a first distributed APM unit 40a connected to the first battery section 26a, a second distributed APM unit 40b connected to the second battery section 26b, and a third distributed APM unit 40c connected to the third battery section 26c. While three distributed APM units are shown, it should be understood that the plurality of distributed APM units 40 may include any number of distributed APM units, and more particularly, at least one distributed APM unit for each of the plurality of battery sections 26. In a non-limiting example, each of the plurality of distributed APM units 40 includes one or more direct current DC to DC converters and associated passive and/or active components configured to convert voltages provided by each of the plurality of battery sections 26 to low-voltage for powering the low-voltage system 20.

In an exemplary embodiment, the distributed APM 28a further includes a distributed APM controller (not shown) for coordinating the operation of each of the plurality of distributed APM units 40. In another exemplary embodiment, the controller 14 executes software to function as the distributed APM controller. In any case, an operation of each of the plurality of distributed APM units 40 may be individually controlled by the controller 14, as will be discussed in greater detail below. In a non-limiting example, as shown in FIG. 2, the plurality of distributed APM units 40 are connected in parallel to the low-voltage terminals 32a, 32b. It should also be understood that one or more of the plurality of distributed APM units 40 may be connected in series to the low-voltage terminals 32a, 32b without departing from the scope of the present disclosure.

Referring to FIG. 3, a schematic diagram of the RESS 16 including a second exemplary embodiment of the APM 28 referred to as a switched APM 28b is shown. In an exemplary embodiment, the switched APM 28b includes a converter unit 42 and a switching module 44. In an exemplary embodiment, the converter unit 42 includes one or more direct current DC to DC converters and associated passive and/or active components configured to convert voltages provided by one of the plurality of battery sections 26 to low-voltage for powering the low-voltage system 20. The converter unit 42 is in electrical communication with the switching module 44 and the low-voltage terminals 32a, 32b.

The switching module 44 is used to electrically connect/disconnect the converter unit 42 to/from any one of the plurality of battery sections 26. In an exemplary embodiment, the switching module 44 includes one or more electrical and/or electromechanical switches operable to electrically connect/disconnect the converter unit 42 to/from any one of the plurality of battery sections 26. In an exemplary embodiment, the switching module 44 is realized using one or more contactors, relays, semiconductor switches, and/or the like. In a non-limiting example, the switching module 44 includes a single pole, n-throw switch, where n is a quantity of the plurality of battery sections 26. The switching module 44 is in electrical communication with each of the plurality of battery sections 26 and the converter unit 42.

In an exemplary embodiment, the switched APM 28b further includes a switched APM controller (not shown) for coordinating the operation of each of the one or more electrical and/or electromechanical switches. In another exemplary embodiment, the controller 14 executes software to function as the switched APM controller. In any case, an operation of the switching module 44 may be controlled by the controller 14, as will be discussed in greater detail below.

Referring again to FIG. 1, the propulsion system 18 is used to convert electrical energy from the RESS 16 to mechanical energy (i.e., rotational energy) to propel the vehicle 12. In an exemplary embodiment, the propulsion system 18 includes a motor controller and an electric motor. The motor controller is used to control the electric motor. In an exemplary embodiment, the motor controller is a power inverter used to convert DC energy from the RESS 16 to alternating current (AC) for driving the electric motor. In a non-limiting example, the electric motor is a three-phase AC induction motor. In a non-limiting example, the electric motor includes a stator having a plurality of stator windings and a rotor having a plurality of rotor windings disposed rotatably within the stator. The stator windings are excited by three-phase AC provided by the power inverter to produce a rotating stator magnetic field. The rotating stator magnetic field induces currents in the rotor windings, which in turn produces a rotor magnetic field which interacts with the rotating stator magnetic field causing the rotor to rotate. The amplitude, frequency, and/or relative phase shift of the excitation of each of the three phases of the stator windings controls speed, direction, and/or torque of the electric motor. It should be understood that the propulsion system 18 may include various additional and/or alternative power electronics and/or electric actuators without departing from the scope of the present disclosure.

The low-voltage system 20 is used to provide energy for auxiliary functions and features of the vehicle 12. In an exemplary embodiment, the low-voltage system 20 includes one or more low-voltage loads such as, for example, lighting, power windows, power mirrors, defrosting systems, ventilation systems, entertainment/infotainment systems, vehicle sensors, driver assistance systems, convenience features (e.g., heated seats), and/or the like. It should be understood that the one or more low-voltage loads may include various additional and/or alternative devices without departing from the scope of the present disclosure. In an exemplary embodiment, the low-voltage system 20 further includes one or more batteries (e.g., lithium-ion batteries, lead-acid batteries, and/or the like) and associated battery charging systems for storage/buffering of energy for the low-voltage loads. In the scope of the present disclosure, low-voltage refers to voltages less than a voltage of the propulsion system 18. In a non-limiting example, the low-voltage is less than 50 v. In a non-limiting example, the low-voltage is 12 v, 24 v, 48 v, or the like. In an exemplary embodiment, the low-voltage system 20 is in electrical communication with the controller 14 such that the controller 14 may control the operation of the low-voltage system 20 (e.g., activate/deactivate the one or more low-voltage loads).

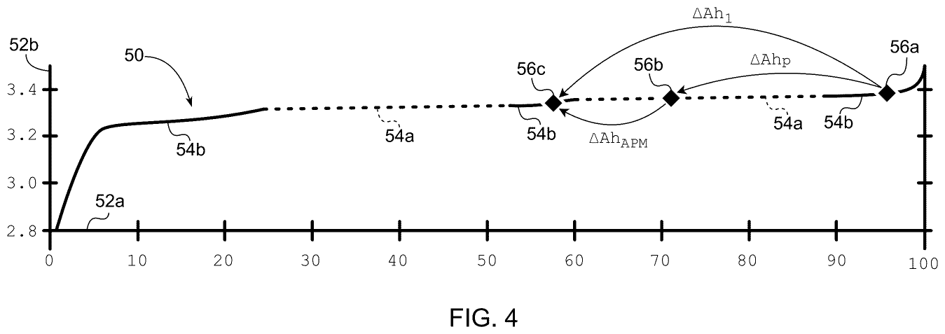

Referring to FIG. 4, a graph including a state of charge curve 50 for an exemplary battery chemistry (e.g., lithium-iron-phosphate) is shown. A horizontal axis 52a of the graph indicates state of charge (e.g., in percent). In the scope of the present disclosure, state of charge is defined as a ratio of an actual amount of charge stored in a battery section to a maximum possible amount of charge which may be stored in the battery section. A vertical axis 52b of the graph indicates open-circuit voltage (e.g., in volts). Therefore, by measuring the open-circuit voltage of one of the plurality of battery sections 26, the state of charge of the one of the plurality of battery sections 26 may be determined using the state of charge curve 50. It should be understood that the shape and scale of the state of charge curve 50 and the values shown in FIG. 4 are merely exemplary in nature.

In an exemplary embodiment, the state of charge curve 50 includes flat regions 54a (denoted by dashed lines) and sloped regions 54b (denoted by solid lines). In the flat regions 54a, a magnitude of a slope of the state of charge curve 50 is relatively small (e.g., near zero). In the sloped regions 54b, the magnitude of the slope of the state of charge curve 50 is non-zero. Therefore, when the measured open-circuit voltage falls within a flat region 54a, a certainty of the state of charge determination based on the state of charge curve 50 is relatively low compared to a certainty of the state of charge determination when the measured open-circuit voltage falls within a sloped region 54b. In a non-limiting example, a certainty of a state of charge determination based on the state of charge curve 50 is quantified in relation to a magnitude of a slope (i.e., a magnitude of a first derivative) of the state of charge curve 50 at the measured open-circuit voltage. In a non-limiting example, the certainty of the state of charge determination is proportional to the magnitude of the slope at the measured open-circuit voltage. In an exemplary embodiment, the sloped regions 54b are defined as regions of the state of charge curve 50 where the certainty of the state of charge determination is greater than or equal to a predetermined state of charge certainty threshold. In a non-limiting example, the predetermined state of charge certainty threshold is equal to a mean state of charge certainty across the entire state of charge curve 50. In another non-limiting example, the predetermined state of charge certainty threshold is equal to a calibratable value (e.g., eighty percent certainty). It should also be understood that the certainty of the state of charge determination may also be related to additional factors besides or in addition to the slope of the state of charge curve 50, including, for example, voltage hysteresis and/or magnitude of error in a voltage hysteresis model.

It should be understood that open-circuit voltage lookup using the state of charge curve 50 is merely an exemplary method for state of charge determination. The state of charge of any of the plurality of battery sections 26 may also be determined using state estimation algorithms such as, for example, Kalman filter algorithms, n-time constant battery models, six parameter battery models, and/or the like. In a non-limiting example, state estimation algorithms process data from measurements performed by the BMS to estimate the state of charge of a battery section.

In an exemplary embodiment, the state estimation algorithm is configured to output the certainty of the state of charge determinations provided by the state estimation algorithm. In another exemplary embodiment, the certainty of the state of charge determinations provided by the state estimation algorithm is quantified based on analysis of internal variables or parameters of the state estimation algorithm, such as, for example, a covariance matrix of a Kalman filter algorithm. In a non-limiting example, when using a state estimation algorithm, the predetermined state of charge certainty threshold is determined using simulation and/or analytical methods to ensure a desired long-term accuracy of the state of charge estimation and/or to ensure convergence of the state estimation algorithm.

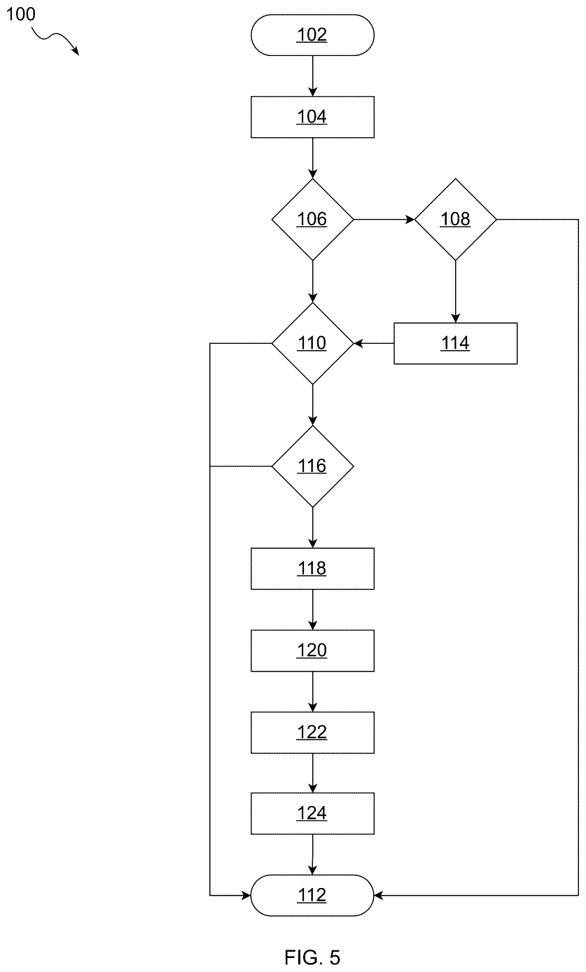

Referring to FIG. 5, a flowchart of the method 100 for determining a state of charge of one or more of the plurality of battery sections 26 is shown. In the following explanation, the method 100 will be discussed in terms of the first battery section 26a. However, it should be understood that the method 100 is equally applicable to any and all of the plurality of battery sections 26. With reference to FIG. 5 and continued reference to FIG. 4, the method 100 begins at block 102 and proceeds to block 104.

At block 104, the controller 14 chooses one of the plurality of battery sections 26 to use to determine the state of charge of each of the plurality of battery sections 26. In an exemplary embodiment, the controller 14 selects the one of the plurality of battery sections 26 based at least in part on a capacity of each of the plurality of battery sections 26. In a non-limiting example, the controller 14 selects one of the plurality of battery sections 26 having a lowest capacity. For the sake of explanation, it is assumed that the first battery section 26a is selected at block 104. However, it should be understood that the following disclosure is also applicable when any of the plurality of battery sections 26 is chosen at block 104. After block 104, the method 100 proceeds to block 106.

At block 106, the controller 14 determines whether a first state of charge has been recorded for the first battery section 26a. In the scope of the present disclosure, the first state of charge is recorded when the RESS 16 is in a known reference state. In the scope of the present disclosure the known reference state is a state where each of the plurality of battery sections 26 have a same state of charge. If the first state of charge for the first battery section 26a has not been determined and recorded, the method 100 proceeds to block 108. If the first state of charge for the first battery section 26a has already been determined and recorded in the media 24 of the controller 14, the method 100 proceeds to block 110.

At block 108, the controller 14 identifies whether the RESS 16 is in the known reference state. As discussed above, the known reference state is a state where each of the plurality of battery sections 26 have a same state of charge. In a non-limiting example, the known reference state is considered to be when each of the plurality of battery sections 26 are within one of the sloped regions 54 of the state of charge curve 50 and have a substantially same state of charge (e.g., within one percent of one another). In another non-limiting example, the known reference state is considered to be when each of the plurality of battery sections 26 have a state of charge between ninety percent and one hundred percent (e.g., at a top-of-charge balance point). In another non-limiting example, the known reference state is considered to be when each of the plurality of battery sections 26 have a state of charge between ten percent and twenty percent (e.g., at a bottom-of-charge balance point). In another non-limiting example, the known reference state is considered to be when each of the plurality of battery sections 26 have a state of charge between sixty percent and seventy percent. If the RESS 16 is not in the known reference state, the method 100 proceeds to enter a standby state at block 112. If the RESS 16 is in the known reference state, the method 100 proceeds to block 114.

At block 114, the controller 14 determines the first state of charge of the first battery section 26a. As discussed above, the first state of charge is determined when the RESS 16 is in the known reference state as determined at block 108. In an exemplary embodiment, to determine the first state of charge of the first battery section 26a, the controller 14 uses the BMS of the RESS 16 to measure the open-circuit voltage of the first battery section 26a and determines the first state of charge of the first battery section 26a based on the state of charge curve 50. In another exemplary embodiment, the controller 14 uses a state estimation algorithm (e.g., a Kalman filter algorithm) to determine the first state of charge based on sensor data from the BMS. The controller 14 saves the first state of charge of the first battery section 26a in the media 24 of the controller 14. In a non-limiting example, the first state of charge is determined at a first point 56a (FIG. 4). Furthermore, at block 114, the controller 14 begins monitoring and recording an amount of charge transferred to/from the first battery section 26a since determination of the first state of charge. In a non-limiting example, the controller 14 uses a current sensor of the BMS to monitor the amount of charge transferred. After block 114, the method 100 proceeds to block 110.

At block 110, the controller 14 determines whether there is a need to determine the state of charge of the plurality of battery sections 26. In an exemplary embodiment, the controller 14 determines a certainty of a state of charge estimate of each of the plurality of battery sections 26. In a non-limiting example, the certainty of the state of charge estimate is provided by a state estimation algorithm (e.g., a Kalman filter algorithm, a recursive least squares algorithm, and/or the like) estimating the state of charge of each of the plurality of battery sections 26. In a non-limiting example, the certainty of the state of charge estimate provided by the state estimation algorithm is quantified based on analysis of internal variables or parameters of the state estimation algorithm, such as, for example, a covariance matrix of a Kalman filter algorithm. In another non-limiting example, the certainty of the state of charge estimate is determined based on a voltage and/or section time tracker model, with deviation of reference voltage and/or balance time as an indicator of certainty. In another non-limiting example, the certainty of the state of charge estimate is determined based on time and/or current passed since a last state of charge estimate update (e.g., amp-hour integration error model).

After determining the certainty of the state of charge estimate, the controller 14 compares the certainty of the state of charge estimate to a predetermined state of charge certainty threshold (e.g., eighty percent certainty). If the certainty of the state of charge estimate is greater than the predetermined state of charge certainty threshold, the method 100 proceeds to enter the standby state at block 112. If the certainty of the state of charge estimate is less than or equal to the predetermined state of charge certainty threshold, the method 100 proceeds to block 116.

At block 116, the controller 14 determines whether there is an opportunity to determine the state of charge of each of the plurality of battery sections 26. In an exemplary embodiment, the controller 14 determines whether there is an opportunity based on preset or learned (e.g., using machine learning) routines of a user of the vehicle 12 to ensure that sufficient energy buffer remains in the RESS 16 to satisfy the needs of the user. For example, if the controller 14 learns or otherwise determines that the vehicle 12 is plugged in to charge overnight, the controller 14 may determine that there is an opportunity to determine the state of charge of each of the plurality of battery sections 26 when the vehicle 12 is plugged in at night. In another example, the controller 14 may learn or otherwise determine a typical amount of battery charge consumed by the user per day, and schedule determination of the updated state of charge estimate such as to ensure that the RESS 16 has sufficient charge for the needs of the user.

In another example, if the controller 14 learns or otherwise determines that the user has planned a long trip which will utilize full capacity of the RESS 16, the controller 14 determines that there is not an opportunity to determine the state of charge of each of the plurality of battery sections 26. In another example, the controller 14 may allow the user to manually activate and/or schedule determination of the state of charge of each of the plurality of battery sections 26. If there is not an opportunity to determine the state of charge of each of the plurality of battery sections 26, or if the user has denied, disabled, or otherwise prevented determination of the state of charge of each of the plurality of battery sections 26, the method 100 proceeds to enter the standby state at block 112. Otherwise, if there is an opportunity to determine the state of charge of each of the plurality of battery sections 26, the method 100 proceeds to block 118.

At block 118, the controller 14 discharges a first amount of charge from the first battery section 26a. In the scope of the present disclosure, the first amount of charge is an amount of charge discharged from only the first battery section 26a using the APM 28 (e.g., measured in amp-hours) since determination of the first state of charge at block 114. In an exemplary embodiment, the controller 14 first determines a maximum permissible amount of charge to discharge from the first battery section 26a. In an exemplary embodiment, the maximum permissible amount of charge to discharge is determined based at least in part on the information about user needs determined at block 116. In a non-limiting example, the controller 14 uses the information about user needs and use of the vehicle 12 in conjunction with a state estimation algorithm (e.g., a Kalman filter algorithm, a recursive least squares algorithm, and/or the like) and/or vehicle range estimate algorithms to determine the maximum permissible amount of charge to discharge based on an estimated range of the vehicle 12.

For example, assuming that a maximum capacity of the first battery section 26a is twenty amp-hours, the controller 14 may use a vehicle range estimation algorithm to determine that ten amp-hours of charge will be required to satisfy the needs of the user. Therefore, the controller 14 determines the maximum permissible amount of charge to discharge to be equal to five amp-hours, leaving five amp-hours remaining as an energy buffer.

In some instances, the maximum permissible amount of charge to discharge may be too low to determine the state of charge of each of the plurality of battery sections 26. In an exemplary embodiment, if the maximum permissible amount of charge to discharge is less than or equal to a minimum discharge threshold, the method 100 proceeds to enter the standby state at block 112. In a non-limiting example, the minimum discharge threshold is a calibratable value (e.g., twenty-five percent of section capacity). In another non-limiting example, the minimum discharge threshold is determined such that the first battery section 26a is in a sloped region 54b of the state of charge curve 50 after discharge.

If the maximum permissible amount of charge to discharge is greater than the minimum discharge threshold, the controller 14 uses the APM 28 to discharge the first battery section 26a. In a non-limiting example, the APM 28 is configured such that the first battery section 26a provides more energy to the low-voltage system 20 than each of the remainder of the plurality of battery sections 26. In another non-limiting example, the APM 28 is configured such that the first battery section 26a provides an entirety of the energy required by the low-voltage system 20. In a first example, the controller 14 activates the first distributed APM unit 40a to discharge the first battery section 26a. In another example, the controller 14 configures the switching module 44 to connect the first battery section 26a to the converter unit 42. The amount of charge discharged from only the first battery section 26a using the APM 28 is recorded using sensors of the BMS and/or the APM 28 and saved in the media 24 of the controller 14.

The first amount of charge is the amount of charge which is discharged only from the first battery section 26a by the APM 28 and not from the remainder of the plurality of battery sections 26. Accordingly, during a time period measured from the execution of block 114 to the conclusion of the execution of block 118, more charge is discharged from the first battery section 26a than from each of the remainder of the plurality of battery sections 26 (e.g., the second battery section 26b, the third battery section 26c, etc.). In other words, the amount of charge discharged from the first battery section 26a within the time period is greater than an amount of charge discharged from any one of the remainder of the plurality of battery sections 26 within the time period. For example, a second point 56b (FIG. 4) represents a state of charge of the remainder of the plurality of battery sections 26 after the time period. It should be understood that the second point 56b (FIG. 4) is merely exemplary in nature, and that the state of charge of some of the remainder of the plurality of battery sections 26 may vary from the second point 56b (FIG. 4) due to differences in section capacity. A third point 56c (FIG. 4) represents a state of charge of the first battery section 26a after the time period.

In an exemplary embodiment, the controller 14 discharges the first battery section 26a until the certainty of the state of charge determination of the first battery section 26a is greater than or equal to the predetermined state of charge certainty threshold (e.g., until the first battery section 26a is within a sloped region 54b of the state of charge curve 50). In another exemplary embodiment, the first battery section 26a is discharged until the maximum permissible amount of charge is removed from the first battery section 26a. As discussed above, the amount of charge which is discharged only from the first battery section 26a by the APM 28 (e.g., measured in amp-hours) since determination of the first state of charge at block 114 is referred to as the first amount of charge.

It should be understood that while the APM 28 is discharging the first battery section 26a, all of the plurality of battery sections 26 (including the first battery section 26a) may simultaneously be discharged by the propulsion system 18 within the scope of the present disclosure. Therefore, the first amount of charge may be represented as:

$$Δ {Ah}_{1 , APM} = Δ {Ah}_{1 , tot} - Δ {Ah}_{P} \qquad ( 1 )$$

where ΔAh_{1,APM} is the first amount of charge (i.e., an amount of charge discharged from only the first battery section 26a using the APM 28), ΔAh_{1,tot} is a total amount of charge discharged from the first battery section 26a, and ΔAh_{P} is an amount of charge discharged from each of the plurality of battery sections 26 (including the first battery section 26a) using the propulsion system 18 and/or the APM 28.

It should be understood that ΔAh_{P} further may include charge added or removed to or from each of the plurality of battery sections 26 (including the first battery section 26a) by any low- or high-voltage loads or sources, including, for example, battery thermal conditioning systems, high-voltage battery chargers, high-voltage cabin ventilation systems, and/or the like. For example, if low- or high-voltage loads result in 5 amp-hours (Ah) of charge discharged from each of the plurality of battery sections 26, ΔAh_{P} is equal to 5 Ah. If the APM 28 is used to additionally discharge 2 Ah from only the first battery section 26a, ΔAh_{1,APM} is equal to 2 Ah and ΔAh_{1,tot} is equal to 7 Ah. After block 118, the method 100 proceeds to block 120.

At block 120, the controller 14 determines a second state of charge of the first battery section 26a. In an exemplary embodiment, the second state of charge is determined at the third point 56c (FIG. 4) after discharge of the first battery section 26a at block 118. In a non-limiting example, to determine the second state of charge of the first battery section 26a, the controller 14 uses the BMS of the RESS 16 to measure the open-circuit voltage of the first battery section 26a and determines the second state of charge of the first battery section 26a based on the state of charge curve 50. In another exemplary embodiment, the controller 14 uses a state estimation algorithm (e.g., a Kalman filter algorithm) to determine the second state of charge based on sensor data from the BMS. The controller 14 saves the second state of charge of the first battery section 26a in the media 24 of the controller 14. In an example as illustrated in FIG. 4, the second state of charge of the first battery section 26a is determined within the sloped region 54b of the state of charge curve 50, thus providing a higher certainty than would be achieved by determining a state of charge of the remainder of the plurality of battery sections 26 within the flat region 54a (e.g., at the second point 56b). After block 120, the method proceeds to block 122.

At block 122, the controller 14 determines the state of charge of each of the plurality of battery sections 26. In an exemplary embodiment, the controller 14 determines the state of charge of each of the plurality of battery sections 26 based at least in part on the first state of charge of the first battery section 26a determined at block 114, the first amount of charge discharged from the first battery section 26a at block 118, and the second state of charge of the first battery section 26a determined at block 120 using a formula:

$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}} \qquad ( 2 )$$

where SOCₙ is a state of charge of an nth battery section of the plurality of battery sections 26, SOC_{1,1} is the first state of charge of the first battery section 26a, C₁ is a capacity of the first battery section 26a, SOC_{1,2} is the second state of charge of the first battery section 26a, ΔAh_{1,APM} is the first amount of charge (also defined above in Equation 1), and Cₙ is a capacity of the nth battery section of the plurality of battery sections 26. In an exemplary embodiment, Equation 2 is used to determine the state of charge of each of the plurality of battery sections 26. The state of charge of each of the plurality of battery sections 26 determined at block 122 is stored in the media 24 of the controller 14 and used for various capabilities and features of the vehicle 12, including range estimation, charging time estimation, capacity estimation, state of health estimation, diagnostics of the RESS 16, and/or the like. After block 122, the method 100 proceeds to block 124.

At block 124, the controller 14 discharges the remainder of the plurality of battery sections 26 (i.e., all of the plurality of battery sections 26 besides the first battery section 26a). In an exemplary embodiment, the amount of charge discharged from only the first battery section 26a using the APM 28 at block 118 (i.e., ΔAh_{APM} in Equation 1) is also discharged from the remainder of the plurality of battery sections 26 to balance the plurality of battery sections 26. In a non-limiting example, the controller 14 uses the APM 28 to transfer energy from the remainder of the plurality of battery sections 26 to the low-voltage system 20 until a state of charge deviation between each of the plurality of battery sections 26 is less than a predetermined state of charge deviation threshold (e.g., one percent). After block 124, the method 100 proceeds to enter the standby state at block 112.

In an exemplary embodiment, the controller 14 repeatedly exits the standby state 112 and restarts the method 100 at block 102. In a non-limiting example, the controller 14 exits the standby state 112 and restarts the method 100 on a timer, for example, every three hundred milliseconds.

The system 10 and method 100 of the present disclosure offer several advantages. By discharging one of the plurality of battery sections 26 to determine the state of charge of each of the plurality of battery sections 26, the one of the plurality of battery sections 26 may be moved out of a flat region 54a of the state of charge curve 50 and into a sloped region 54b of the state of charge curve 50, increasing an accuracy of the state of charge determination. Furthermore, by selecting one of the plurality of battery sections 26 having a lowest capacity at block 104, the one of the plurality of battery sections 26 is more quickly moved out of a flat region 54a of the state of charge curve 50 and into a sloped region 54b of the state of charge curve 50. Additionally, the system 10 and method 100 allow for determination of the state of charge of each of the plurality of battery sections 26 even when most/all of the plurality of battery sections 26 are within a flat region 54a of the state of charge curve 50, allowing for more frequent accurate state of charge determinations without unnecessary depletion of the entire RESS 16.

Furthermore, by using the distributed APM 28a or the switched APM 28b, each of the plurality of battery sections 26 may be individually discharged to provide power to the low-voltage system 20. By discharging the one of the plurality of battery sections 26 using the APM 28, the energy is used to power functions and features of the vehicle 12 via the low-voltage system 20, thus increasing efficiency. Additionally, the system 10 and method 100 have wide applicability to various additional applications of high-voltage rechargeable energy storage systems, including, for example, residential/commercial energy storage systems, grid energy storage systems, and/or the like.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A method for determining a state of charge of each of a plurality of battery sections of a rechargeable energy storage system (RESS), the method comprising:
determining a first state of charge of a first battery section of the plurality of battery sections;
discharging a first amount of charge from the first battery section in response to determining the first state of charge of the first battery section;
determining a second state of charge of the first battery section in response to discharging the first amount of charge from the first battery section; and
determining the state of charge of each of the plurality of battery sections based at least in part on the first state of charge, the first amount of charge, and the second state of charge.

2. The method of claim 1, wherein discharging the first amount of charge from the first battery section further comprises:
determining a certainty of a state of charge estimate of each of the plurality of battery sections;
comparing the certainty of the state of charge estimate of each of the plurality of battery sections to a predetermined state of charge certainty threshold; and
discharging the first amount of charge from the first battery section in response to determining that the certainty of the state of charge estimate of one or more of the plurality of battery sections is less than the predetermined state of charge certainty threshold.

3. The method of claim 1, wherein discharging the first amount of charge from the first battery section further comprises:
determining a maximum permissible amount of charge to discharge from the first battery section;
determining the first amount of charge based at least in part on the maximum permissible amount of charge, wherein the first amount of charge is less than or equal to the maximum permissible amount of charge; and
discharging the first amount of charge from the first battery section in response to determining the first amount of charge.

4. The method of claim 1, wherein discharging the first amount of charge from the first battery section further comprises:
discharging the first battery section until a certainty of a state of charge estimate of the first battery section is greater than or equal to a predetermined state of charge certainty threshold, wherein the first amount of charge is equal to a total amount of charge removed from the first battery section while discharging the first battery section.

5. The method of claim 1, wherein discharging the first amount of charge from the first battery section further comprises:
discharging the first amount of charge at least in part using an auxiliary power module (APM) configured to provide energy to low-voltage loads.

6. The method of claim 5, wherein discharging the first amount of charge from the first battery section further comprises:
discharging the first amount of charge at least in part using the APM, wherein the APM is a distributed APM including a plurality of distributed APM units, wherein each of the plurality of distributed APM units is configured to discharge one of the plurality of battery sections.

7. The method of claim 5, wherein discharging the first amount of charge from the first battery section further comprises:
discharging the first amount of charge at least in part using the APM, wherein the APM is a switched APM including a converter unit and a switching module, wherein the switching module is configured to electrically connect the converter unit to any one of the plurality of battery sections.

8. The method of claim 1, wherein determining the state of charge of each of the plurality of battery sections further comprises:
determining the state of charge of each of the plurality of battery sections based at least in part on the first state of charge, the first amount of charge, and the second state of charge using a formula:
$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}}$$
wherein SOCₙ is a state of charge of an nth battery section of the plurality of battery sections, SOC_{1,1} is the first state of charge of the first battery section, C₁ is a capacity of the first battery section, SOC_{1,2} is the second state of charge of the first battery section, ΔAh_{1,APM} is the first amount of charge, and Cₙ is a capacity of the nth battery section of the plurality of battery sections.

9. The method of claim 1, wherein determining the first state of charge further comprises:
determining the first state of charge at a known reference state of the RESS, wherein in the known reference state, each of the plurality of battery sections have a same state of charge.

10. The method of claim 9, wherein determining the first state of charge further comprises:
determining the first state of charge, wherein the first state of charge is between ninety percent and one hundred percent.

11. A system for determining a state of charge of each of a plurality of battery sections of a rechargeable energy storage system (RESS) of a vehicle, the system comprising:
the RESS including the plurality of battery sections electrically connected in series;
an auxiliary power module (APM) in electrical communication with the RESS, wherein the APM is configured to discharge one or more of the plurality of battery sections;
a controller in electrical communication with the plurality of battery sections and the APM, wherein the controller is programmed to:
determine a first state of charge of a first battery section of the plurality of battery sections;
discharge a first amount of charge from the first battery section in response to determining the first state of charge of the first battery section;
determine a second state of charge of the first battery section in response to discharging the first amount of charge from the first battery section; and
determine the state of charge of each of the plurality of battery sections based at least in part on the first state of charge, the first amount of charge, and the second state of charge.

12. The system of claim 11, wherein to discharge the first amount of charge from the first battery section, the controller is further programmed to:
determine a certainty of a state of charge estimate of each of the plurality of battery sections;
compare the certainty of the state of charge estimate of each of the plurality of battery sections to a predetermined state of charge certainty threshold; and
discharge the first amount of charge from the first battery section in response to determining that the certainty of the state of charge estimate of one or more of the plurality of battery sections is less than the predetermined state of charge certainty threshold, wherein the first battery section is discharged until a certainty of a state of charge estimate of the first battery section is greater than or equal to the predetermined state of charge certainty threshold, and wherein the first amount of charge is equal to a total amount of charge removed from the first battery section while discharging the first battery section.

13. The system of claim 11, wherein to discharge the first amount of charge from the first battery section, the controller is further programmed to:
determine a maximum permissible amount of charge to discharge from the first battery section based at least in part on an estimated range of the vehicle;
determine the first amount of charge based at least in part on the maximum permissible amount of charge, wherein the first amount of charge is less than or equal to the maximum permissible amount of charge; and
discharge the first amount of charge from the first battery section in response to determining the first amount of charge.

14. The system of claim 11, wherein the APM is configured to provide the first amount of charge to one or more low-voltage loads of the vehicle, wherein the APM is a distributed APM including a plurality of distributed APM units, and wherein each of the plurality of distributed APM units is configured to discharge one of the plurality of battery sections.

15. The system of claim 11, wherein the APM is configured to provide the first amount of charge to one or more low-voltage loads of the vehicle, wherein the APM is a switched APM including a converter unit and a switching module, and wherein the switching module is configured to electrically connect the converter unit to any one of the plurality of battery sections.

16. The system of claim 11, wherein to determine the state of charge of each of the plurality of battery sections, the controller is further programmed to:
determine the state of charge of each of the plurality of battery sections based at least in part on the first state of charge, the first amount of charge, and the second state of charge using a formula:
$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}}$$
wherein SOCₙ is a state of charge of an nth battery section of the plurality of battery sections, SOC_{1,1} is the first state of charge of the first battery section, C₁ is a capacity of the first battery section, SOC_{1,2} is the second state of charge of the first battery section, ΔAh_{1,APM} is the first amount of charge, and Cₙ is a capacity of the nth battery section of the plurality of battery sections.

17. The system of claim 11, wherein the controller is further programmed to:
discharge a remainder of the plurality of battery sections using the APM in response to determining the state of charge of each of the plurality of battery sections, wherein the remainder of the plurality of battery sections are discharged such that a state of charge deviation between each of the plurality of battery sections is less than a predetermined state of charge deviation threshold.

18. A method for determining a state of charge of each of a plurality of battery sections of a rechargeable energy storage system (RESS) of a vehicle, the method comprising:
determining a first state of charge of a first battery section of the plurality of battery sections;
discharging a first amount of charge from the first battery section within a time period at least in part using an auxiliary power module (APM) configured to provide energy to low-voltage loads of the vehicle in response to determining the first state of charge of the first battery section, wherein the first amount of charge is greater than an amount of charge discharged from a remainder of the plurality of battery sections within the time period;
determining a second state of charge of the first battery section in response to discharging the first amount of charge from the first battery section; and
determining the state of charge of each of the plurality of battery sections based at least in part on the first state of charge, the first amount of charge, and the second state of charge using a formula:
$${SOC}_{n} = {SOC}_{1 , 1} - \frac{{C}_{1} * {SOC}_{1 , 1} - {C}_{1} * {SOC}_{1 , 2} - Δ {Ah}_{1 , APM}}{{C}_{n}}$$
wherein SOCₙ is a state of charge of an nth battery section of the plurality of battery sections, SOC_{1,1} is the first state of charge of the first battery section, C₁ is a capacity of the first battery section, SOC_{1,2} is the second state of charge of the first battery section, ΔAh_{1,APM} is the first amount of charge, and Cₙ is a capacity of the nth battery section of the plurality of battery sections.

19. The method of claim 18, wherein discharging the first amount of charge from the first battery section further comprises:
determining a certainty of a state of charge estimate of each of the plurality of battery sections;
comparing the certainty of the state of charge estimate of each of the plurality of battery sections to a predetermined state of charge certainty threshold; and
discharging the first amount of charge from the first battery section in response to determining that the certainty of the state of charge estimate of one or more of the plurality of battery sections is less than the predetermined state of charge certainty threshold.

20. The method of claim 19, wherein discharging the first amount of charge from the first battery section further comprises:
determining a maximum permissible amount of charge to discharge from the first battery section based at least in part on an estimated range of the vehicle; and
discharging the first battery section until a certainty of a state of charge estimate of the first battery section is greater than or equal to the predetermined state of charge certainty threshold or until the maximum permissible amount of charge has been discharged from the first battery section, and wherein the first amount of charge is equal to a total amount of charge removed from the first battery section while discharging the first battery section.
